(19) United States
(12) Patent Application Publication
(10) Pub. No.: US 2017/0068056 A1
(43) Pub. Date: Mar. 9, 2017

(54) DEVICE MOUNTING APPARATUS AND DEVICE MOUNTING METHOD

(71) Applicant: FUJITSU COMPONENT LIMITED, Tokyo (JP)

(72) Inventors: Rie Gappa, Tokyo (JP); Takeshi Komiyama, Tokyo (JP)

(21) Appl. No.: 15/249,566

(22) Filed: Aug. 29, 2016

(30) Foreign Application Priority Data
Sep. 3, 2015 (JP) 2015-174084

(51) Int. Cl. G02B 6/42; H04N 5/247; H01L 23/00; H04N 7/18

(52) U.S. Cl. CPC G02B 6/422; H04N 7/181; H04N 5/247; H01L 24/75; H01L 24/81; G02B 6/4214; G02B 6/4245; H01L 2924/12042; H01L 2924/12043; H01L 2224/75843; H01L 2224/75753; H01L 2224/81121; H01L 2224/81205

(57) ABSTRACT

A mounting apparatus for mounting a device onto a substrate includes a table that holds the substrate, a mounting head that carries a device to be mounted on the substrate, a camera that is movable to a position between the table and the mounting head and includes a first imager that captures an image of the substrate on the table and a second imager that captures images of the device carried by the mounting head, a third imager that captures an image of a first device mounted on the substrate, and a controller that controls the mounting head to position a second device to be mounted on the substrate and being carried by the mounting head based on a position of the first device that is determined based on the image captured by the third imager.

### CROSS-REFERENCE TO RELATED APPLICATION

The present application is based upon and claims the benefit of priority of Japanese Patent Application No. 2015-174084, filed on Sep. 3, 2015, the entire contents of which are incorporated herein by reference.

### BACKGROUND OF THE INVENTION

1. Field of the Invention

An aspect of this disclosure relates to a device mounting apparatus and a device mounting method.

2. Description of the Related Art

An optical module used in the field of optical communication includes a light-emitting device and a light-receiving device mounted on an optical waveguide. For example, an optical module is used for high-speed optical communications performed by, for example, supercomputers and high-end servers using high-speed interfaces.

A certain type of optical module is formed by sequentially stacking a lens sheet and a flexible substrate (“substrate”) on which a light-emitting device and a light-receiving device are mounted on an optical waveguide. In such an optical module, the light-emitting device and the light-receiving device are aligned with the optical waveguide so that light from the light-emitting device can enter the optical waveguide and light from the optical waveguide can enter the light-receiving device (see, for example, Japanese Laid-Open Patent Publication No. 2009-69360).

Because even slight misalignment of the light-emitting device and the light-receiving device results in the loss of light emitted from the light-emitting device and received by the light-receiving device, it is necessary to accurately align the light-emitting device and the light-receiving device with the optical waveguide. However, it is difficult to perform accurate alignment, and the light-emitting device and the light-receiving device may be mounted on positions slightly different from desired positions. Such slight misalignment may reduce the characteristics and the yield of optical modules.

### SUMMARY OF THE INVENTION

In an aspect of this disclosure, there is provided a mounting apparatus for mounting a device onto a substrate. The mounting apparatus includes a table that holds the substrate, a mounting head that carries a device to be mounted on the substrate, a camera that is movable to a position between the table and the mounting head and includes a first imager that captures an image of the substrate on the table and a second imager that captures images of the device carried by the mounting head, a third imager that captures an image of a first device mounted on the substrate, and a controller that controls the mounting head to position a second device to be mounted on the substrate and being carried by the mounting head based on a position of the first device that is determined based on the image captured by the third imager.

### BRIEF DESCRIPTION OF THE DRAWINGS

FIG. 1 is a top view of an optical module;

FIG. 2 is a cut-away side view of an optical module;

FIGS. 3A and 3B are drawings illustrating a device mounting method;

FIGS. 4A and 4B are drawings illustrating a device mounting method;

FIGS. 5A through 5C are drawings illustrating positional relationships between light-emitting and light-receiving devices and through holes;

FIG. 6 is a drawing illustrating an exemplary configuration of a device mounting apparatus according to a first embodiment;

FIGS. 7A and 7B are drawings illustrating a device mounting method according to the first embodiment;

FIGS. 8A and 8B are drawings illustrating a device mounting method according to the first embodiment;

FIG. 9 is a drawing illustrating an exemplary configuration of a device mounting apparatus according to a second embodiment;

FIG. 10 is a drawing illustrating an exemplary configuration of a device mounting apparatus according to a third embodiment;

FIGS. 11A and 11B are drawings illustrating an exemplary configuration of a device mounting apparatus according to a fourth embodiment;

FIGS. 12A and 12B are drawings illustrating an exemplary configuration of a device mounting apparatus according to a fifth embodiment;

FIGS. 13A and 13B are drawings illustrating a device mounting method according to a sixth embodiment;

FIGS. 14A and 14B are drawings illustrating a device mounting method according to the sixth embodiment;

FIG. 15 is a drawing illustrating a device mounting method according to the sixth embodiment; and

FIG. 16 is a flowchart illustrating a device mounting method according to the sixth embodiment.

### DESCRIPTION OF EMBODIMENTS

Embodiments of the present invention are described below with reference to the accompanying drawings. Below, the same reference number is assigned to the same components, and repeated descriptions of those components are omitted.

### <Optical Module>

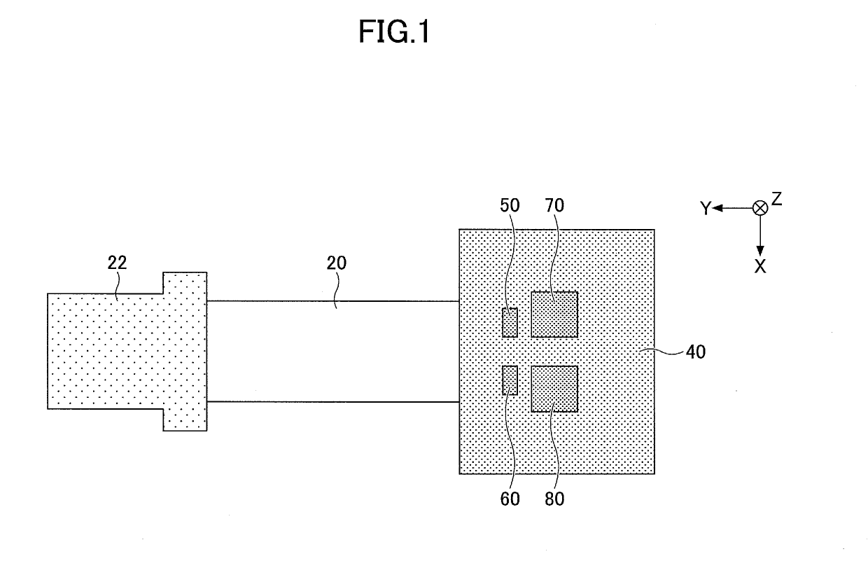

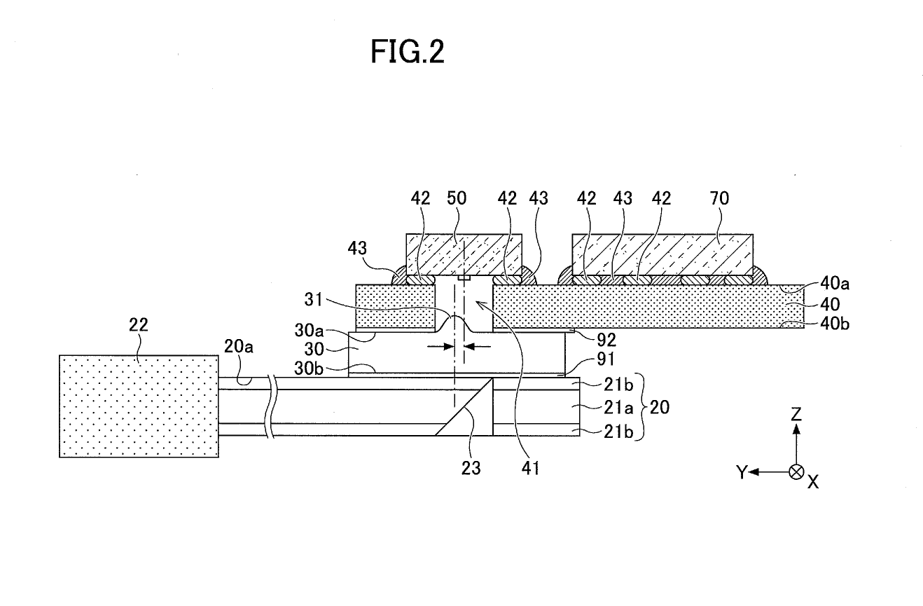

First, an optical module according to an embodiment is described. FIG. 1 is a top view of the optical module, and FIG. 2 is a cut-away side view of the optical module. The optical module is formed by stacking a lens sheet 30 and a flexible substrate (“substrate”) 40 on a sheet-shaped optical waveguide 20. The optical waveguide 20 has a structure where a center core 21a is sandwiched between and surrounded by clads 21b. A lens ferrule 22 is attached to one end of the optical waveguide 20, and a mirror 23 is formed near the other end of the optical waveguide 20. The lens sheet 30 includes multiple lenses 31 formed on a first surface 30a, and a second surface 30b that is bonded to the optical waveguide 20 via an adhesive sheet 91.

Wiring (not shown) is formed on the substrate 40. A light-emitting device 50, a light-receiving device 60, a driver 70, and a transimpedance amplifier (TIA) 80 are mounted on a first surface 40a of the substrate 40. The light-emitting device 50 may be, for example, a vertical-cavity surface-emitting laser (VCSEL), and the light-receiving device 60 may be, for example, a photodiode. The driver 70 is an integrated circuit (IC) for driving the light-emitting device 50. The TIA 80 is an IC for converting a current which is generated by the light-receiving device 60 based on detected light into a voltage. One of the light-emitting device 50 and the light-receiving device 60 may be referred to as a “first device” and the other one of the light-emitting device 50 and the light-receiving device 60 may be referred to as a “second device”.

Through holes 41 are formed in the substrate 40 as optical paths for light emitted from the light-emitting device 50 and light entering the light-receiving device 60. The first surface 30a of the lens sheet 30 is bonded to a second surface 40b of the substrate 40 via an adhesive sheet 92. The light-emitting device 50, the light-receiving device 60, the driver 70, and the TIA 80 mounted on the substrate 40 are connected to the wiring formed on the substrate 40 via bumps 42. The bumps 42 are made of a metal such as gold. Also, spaces between the bumps 42 and the light-emitting device 50, the light-receiving device 60, the driver 70, and the TIA 80 are filled with a resin 43.

The optical module is assembled such that the light-emitting device 50 and light-receiving device 60, the through holes 41, the lenses 31, and the mirror 23 are aligned with each other. More specifically, components of the optical module are aligned and joined together such that light emitted from the light-emitting device 50 passes through the corresponding through hole 41 and the corresponding lens 31, is reflected by the mirror 23, and propagates through the core 21a of the optical waveguide 20; and light propagating through the core 21a is reflected by the mirror 23, passes through the corresponding lens 31 and the corresponding through hole 41, and enters the light-receiving device 60.

The bumps 42 are formed on the first surface 40a; and the light-emitting device 50, the light-receiving device 60, the driver 70, and the TIA 80 are positioned and mounted on the bumps 42 and are bonded together by ultrasonic flip-chip bonding. Thereafter, thermoset resin is injected into spaces between the bumps 42 and the components, and is thermally hardened.

Separately from the above process, the lens ferrule 22 is attached to one end of the optical waveguide 20, the adhesive sheet 91 is bonded to the surface 20a of the optical waveguide 20, and the second surface 30b of the lens sheet 30 is bonded to the adhesive sheet 91. When the lens sheet 30 is bonded to the adhesive sheet 91, the mirror 23 and the lenses 31 are aligned with each other.

Next, the adhesive sheet 92 is bonded to the first surface 30a of the lens sheet 30, and the second surface 40b of the substrate 40 is bonded to the adhesive sheet 92. When the substrate 40 is bonded to the adhesive sheet 92, the lenses 31, the through holes 41, and the light-emitting and light-receiving devices 50 and 60 are aligned with each other.

The process of mounting the light-emitting device 50 and the light-receiving device 60 on the substrate 40 is described below in more detail.

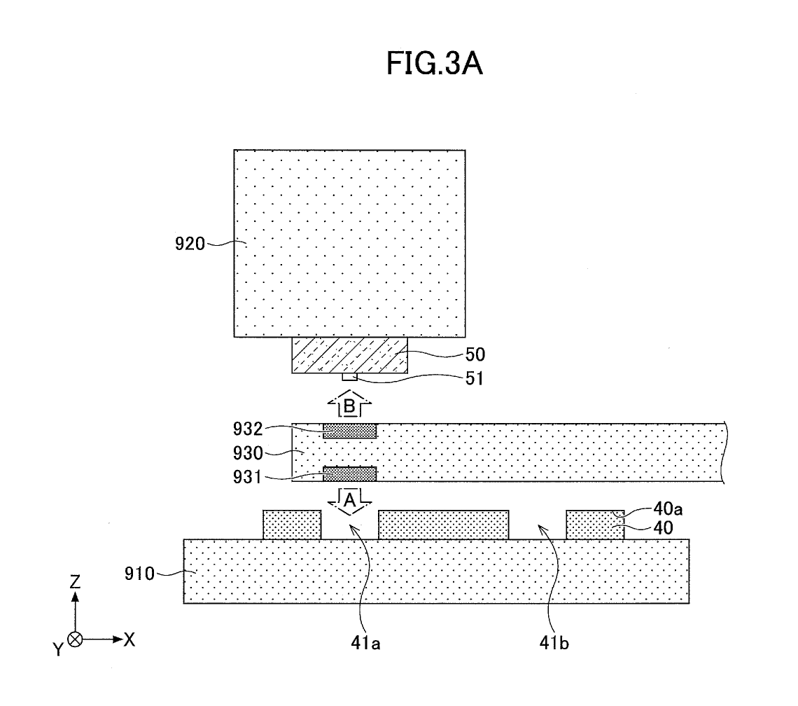

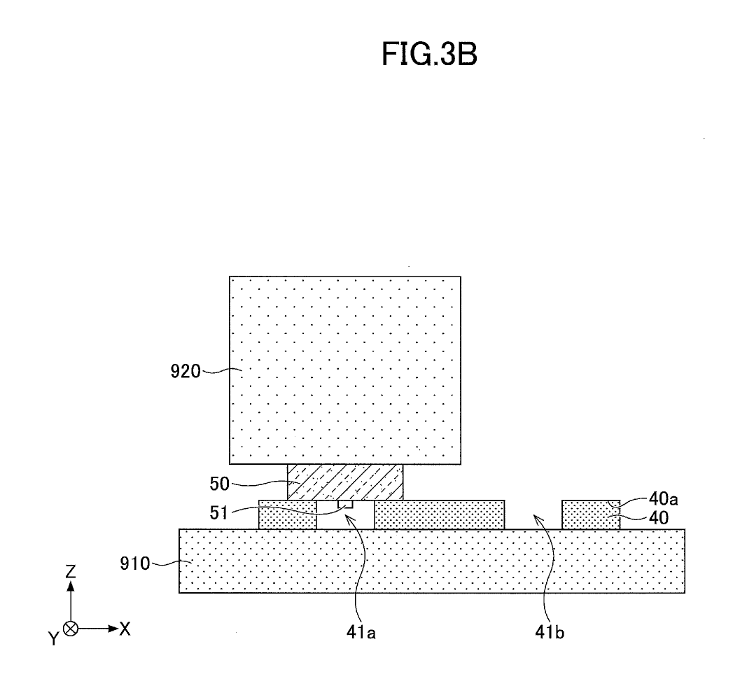

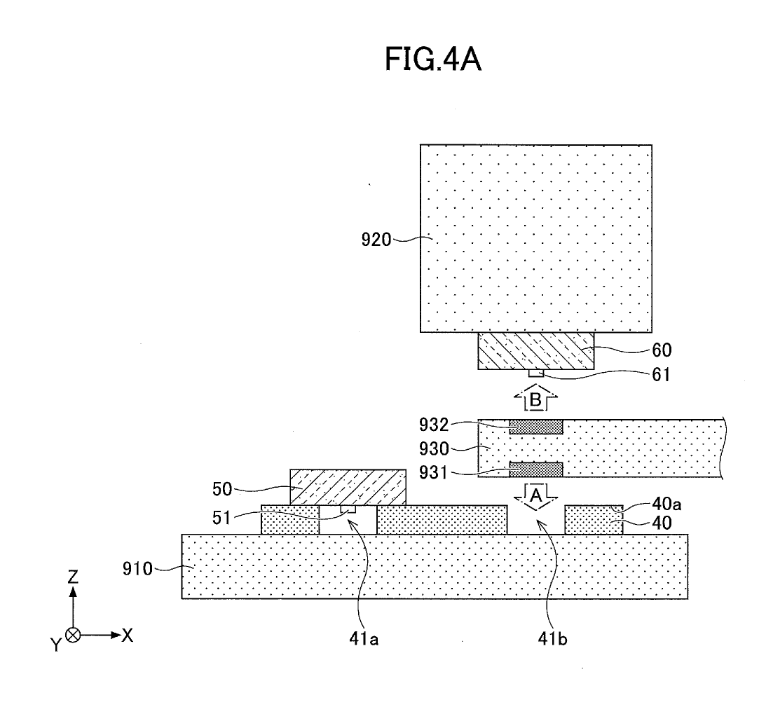

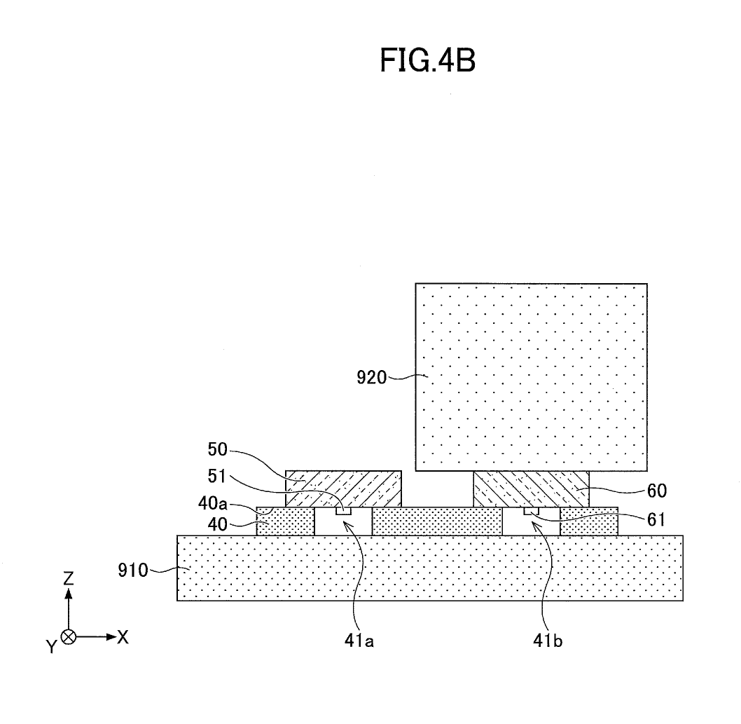

To bond the light-emitting device 50 and the light-receiving device 60 to the substrate 40 by ultrasonic flip-chip bonding, a flip-chip bonding apparatus illustrated in FIGS. 3A through 4B is used. The flip-chip bonding apparatus includes a table 910 on which the substrate 40 is placed, a mounting head 920 for carrying the light-emitting device 50 and the light-receiving device 60, and a double-sided camera 930 that can capture images of objects above and below the camera 930.

The camera 930 includes a first imager 931 on a first side and a second imager 932 on a second side. The imaging direction of the first imager 931 indicated by an arrow A is 180-degrees opposite the imaging direction of the second imager 932 indicated by an arrow B. Thus, the first imager 931 captures an image of the substrate 40 placed on the table 910, and the second imager 932 captures images of the light-emitting device 50 and the light-receiving device 60 held by the mounting head 920.

First, as illustrated by FIG. 3A, the light-emitting device 50 is held by the mounting head 920, and is aligned with a through hole 41a. Bumps for mounting the light-emitting device 50 are formed around the through hole 41a.

The camera 930 is moved to a position between the substrate 40 on the table 910 and the light-emitting device 50 held by the mounting head 920. An image of the substrate 40 located in a −Z direction relative to the camera 930 is captured by the first imager 931, and an image of the light-emitting device 50 located in a +Z direction relative to the camera 930 is captured by the second imager 932. Based on the position of the through hole 41a captured by the first imager 931 and the position of a light emitter 51 of the light-emitting device 50 captured by the second imager 932, the mounting head 920 is moved to align the light-emitting device 50 with the through hole 41a such that the light emitter 51 is placed in a desired position in the through hole 41a.

Next, as illustrated by FIG. 3B, the camera 930 is moved in a +X direction (right in FIG. 33) to a position outside of the space below the light-emitting device 50, the mounting head 920 is moved in the −Z direction (downward in FIG. 3B) to place the light-emitting device 50 on the substrate 40, and the light-emitting device 50 is bonded to the substrate 40 by flip-chip bonding.

Next, as illustrated by FIG. 4A, the light-receiving device 60 is held by the mounting head 920, and is aligned with the through hole 41b formed in the substrate 40. Bumps for mounting the light-receiving device 60 are formed around the through hole 41b.

The camera 930 is moved to a position between the substrate 40 and the light-receiving device 60. An image of the first surface 40a located in the −Z direction is captured by the first imager 931, and an image of the light-receiving device 60 located in the +Z direction is captured by the second imager 932. Based on the position of the through hole 41b captured by the first imager 931 and the position of a light receiver 61 of the light-receiving device 60 captured by the second imager 932, the mounting head 920 is moved to align the light-receiving device 60 with the through hole 41b such that the light receiver 61 is placed in a desired position in the through hole 41b.

Next, as illustrated by FIG. 4B, the camera 930 is moved in the +X direction in FIG. 4B, the mounting head 920 is moved in the −Z direction in FIG. 4B to place the light-receiving device 60 on the substrate 40, and the light-receiving device 60 is bonded to the substrate 40 by flip-chip bonding.

Through the above process, the light-emitting device 50 and the light-receiving device 60 are mounted on the substrate 40. In FIGS. 3A through 4B, only one light emitter 51 and only one light receiver 61 are illustrated for brevity.

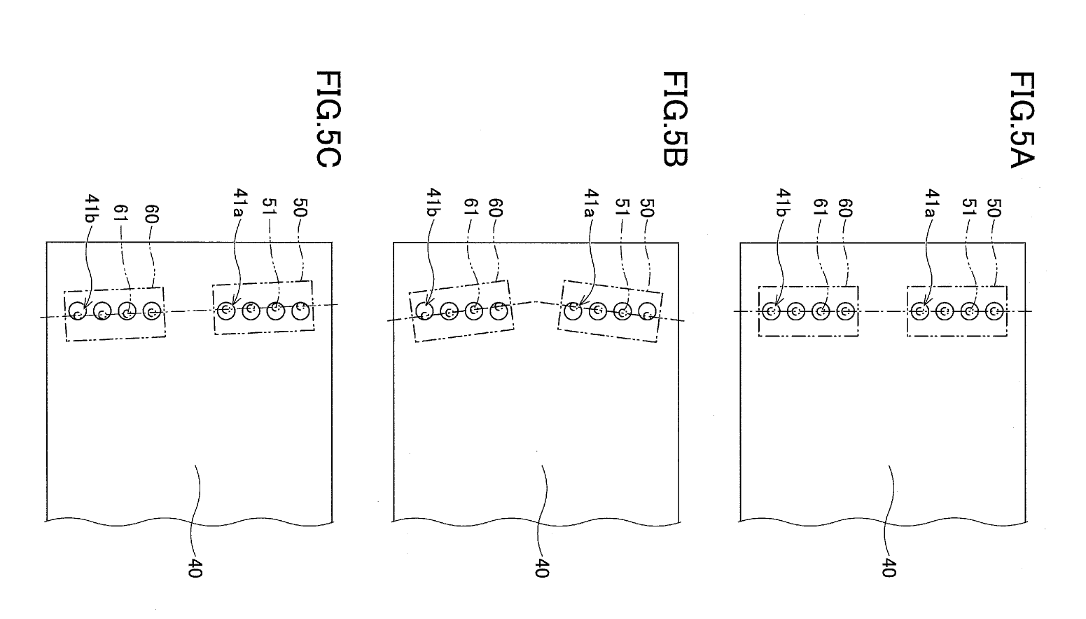

Each of FIGS. 5A through 5C illustrates the light-emitting device 50 and the light-receiving device 60 that are bonded to the substrate 40. In FIGS. 5A through 5C, the light-emitting device 50 includes four light emitters 51 and the light-receiving device 60 includes four light receivers 61. In FIGS. 5A through 5C, each dashed-dotted line connects the four light emitters 51 and the four light receivers 61.

As illustrated by FIG. 5A, the light-emitting device 50 and the light-receiving device 60 are ideally or preferably bonded to the substrate 40 such that each of the light emitters 51 is positioned in the center of the corresponding one of four through holes 41a, and each of the light receivers 61 is positioned in the center of the corresponding one of four through holes 41b. With this alignment, the loss of light is small. In FIG. 5A, the light emitters 51 and the light receivers 61 are collinear.

In the above process, however, the step of aligning the through holes 41a with the light emitters 51 and bonding the light-emitting device 50 to the substrate 40 is performed separately from the step of aligning the through holes 41b with the light receivers 61 and bonding the light-receiving device 60 to the substrate 40. For this reason, as illustrated by FIG. 5B, there is a case where the light emitters 51 of the bonded light-emitting device 50 are misaligned with the centers of the corresponding through holes 41a, and the light receivers 61 of the bonded light-receiving device 60 are misaligned with the centers of the corresponding through holes 41b. In FIG. 5B, the light emitters 51 are not collinear with the light receivers 61. In this case, the lenses 31 of the lens sheet 30 to be bonded at a later step are also misaligned with the light emitters 51 and the light receivers 61, which results in the loss of light.

FIG. 5C illustrates still another case. In FIG. 5C, although the light emitters 51 are misaligned with the centers of the corresponding through holes 41a and the light receivers 61 are misaligned with the centers of the corresponding through holes 41b, the light emitters 51 are collinear with the light receivers 61. In this case, by properly positioning and bonding the lens sheet 30 at a later step, it is possible to properly align the light emitters 51 and the light receivers 61 with the corresponding lenses 31 such that the loss of light is reduced.

### First Embodiment

Next, a first embodiment is described. The first embodiment provides a device mounting apparatus and a device mounting method that can band the light-emitting device 50 and the light-receiving device 60 to the substrate 40 such that the light emitters 51 are aligned collinearly with the light receivers 61.

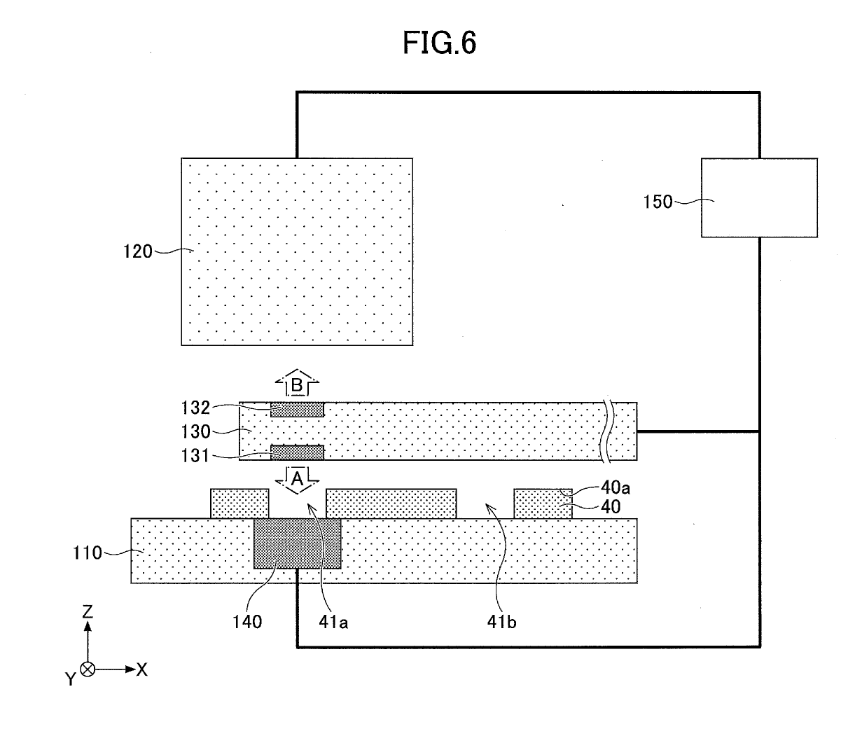

FIG. 6 illustrates a flip-chip bonding apparatus that is a device mounting apparatus of the first embodiment. The device mounting apparatus includes a table 110 on which the substrate 40 is to be placed, a mounting head 120 for carrying the light-emitting device 50 and the light-receiving device 60, a double-sided first camera 130 that is capable of capturing images of objects above and below the first camera 130, a second camera 140 embedded in the table 110, and a controller 150 that controls the position of the mounting head 120 based on images captured by the first camera 130 and the second camera 140. The controller 150 controls the entire device mounting apparatus.

The first camera 130 includes a first imager 131 on a first side and a second imager 132 on a second side.

The imaging direction of the first imager 131 (indicated by an arrow A) is 180-degrees opposite the imaging direction of the second imager 132 (indicated by an arrow B). Thus, the first imager 131 can capture an image of the substrate 40 placed on the table 110, and the second imager 132 can capture images of the light-emitting device 50 and the light-receiving device 60 held by the mounting head 120.

The device mounting apparatus of the first embodiment includes the second camera 140 used as a third imager. The second camera 140 captures an image of the light-emitting device 50 mounted on the substrate 40, especially the light emitters 51.

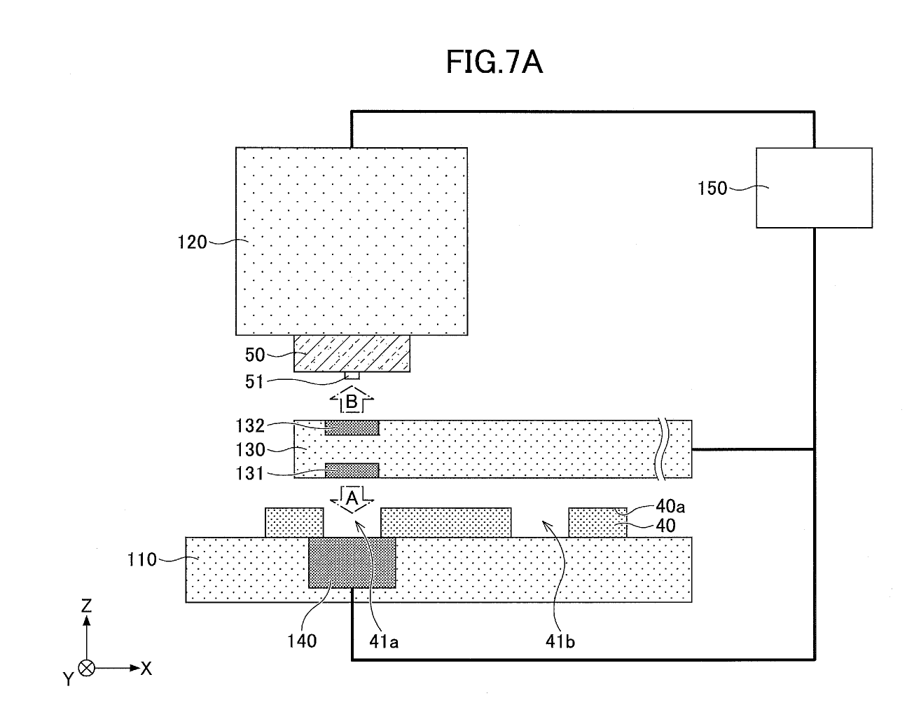

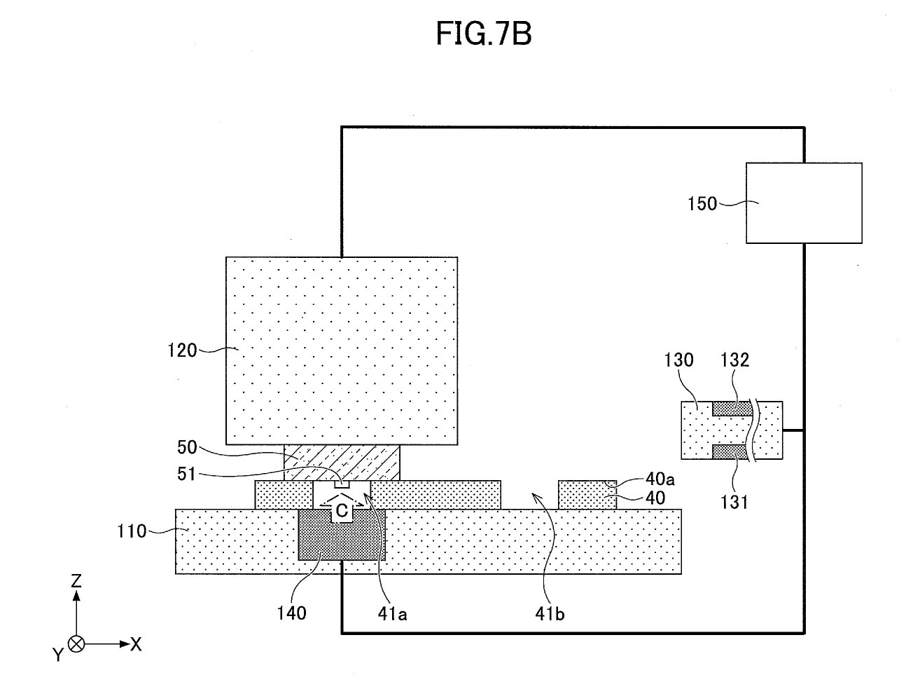

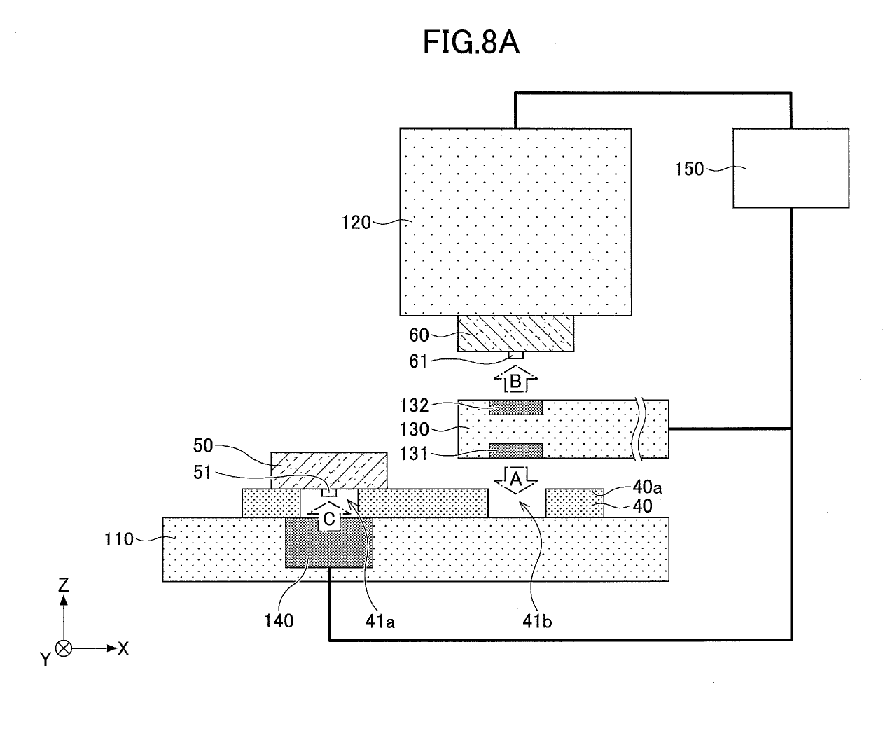

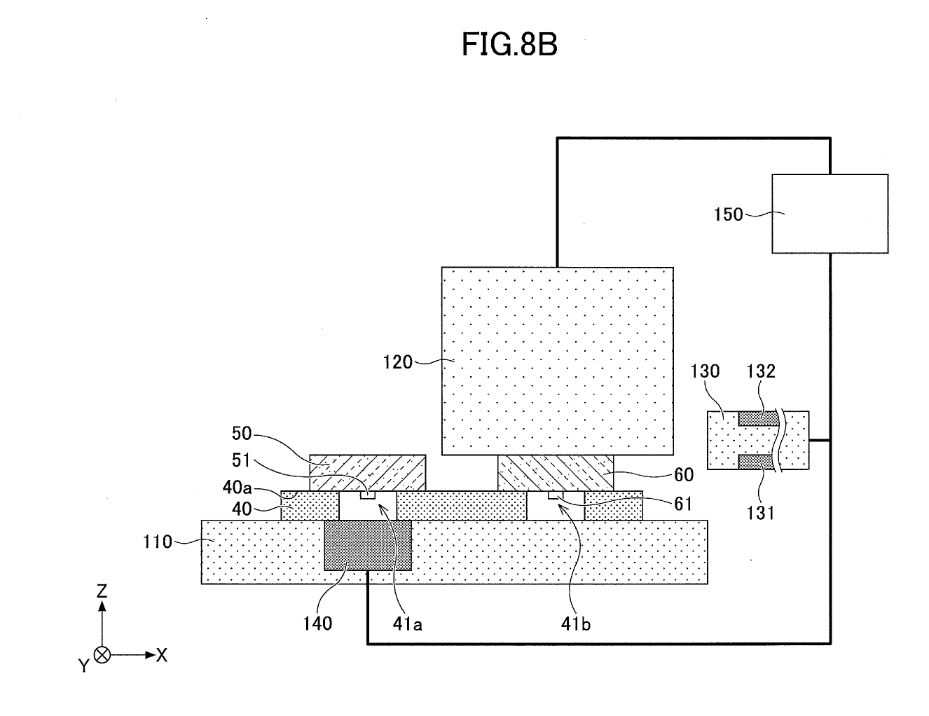

Next, a device mounting method of the first embodiment is described with reference to FIGS. 7A through 8B. In FIGS. 7A through 8B, only one light emitter 51 and only one light receiver 61 are illustrated for brevity.

First, as illustrated by FIG. 7A, the light-emitting device 50 held by the mounting head 120 is aligned with the through hole 41a. The through hole 41a is formed in an area of the substrate 40 where the light-emitting device 50 is to be mounted, and the through hole 41b is formed in an area of the substrate 40 where the light-receiving device 60 is to be mounted. Bumps (not shown) for mounting the light-emitting device 50 are formed around the through hole 41a. The first camera 130 is moved to a position between the substrate 40 and the light-emitting device 50. An image of the first surface 40a of the substrate 40 located in the −Z direction is captured by the first imager 131, and an image of the light-emitting device 50 located in the +Z direction is captured by the second imager 132. Based on the position of the through hole 41a captured by the first imager 131 and the position of the light emitter 51 captured by the second imager 132, the mounting head 120 is moved to align the light-emitting device 50 with the through hole 41a such that the light emitter 51 is placed in a desired position in the through hole 41a.

Next, as illustrated by FIG. 7B, the first camera 130 is moved in the +X direction in FIG. 7B, the mounting head 120 is moved in the −Z direction in FIG. 7B to place the light-emitting device 50 on the substrate 40, and the light-emitting device 50 is bonded to the substrate 40. In the present embodiment, before the light-emitting device 50 is bonded, an image of the light-emitting 50, especially light emitters 51, may be captured by the second camera 140, and the light-emitting device 50 may be adjusted to a desired position by moving the mounting head 120 based on the captured image.

Next, as illustrated by FIG. 8A, the light-receiving device 60 held by the mounting head 120 is aligned with the through hole 41b. Bumps for mounting the light-receiving device 60 are formed around the through hole 41b. The first camera 130 is moved to a position between the substrate 40 and the light-receiving device 60. An image of the first surface 40a located in the −Z direction is captured by the first imager 131, and an image of the light-receiving device 60 located in the +Z direction is captured by the second imager 132. Based on the position of the through hole 41b captured by the first imager 131 and the position of the light receiver 61 of the light-receiving device 60 captured by the second imager 132, the mounting head 120 is moved to align the light-receiving device 60 with the through hole 41b such that the light receiver 61 is placed in a desired position in the through hole 41b. Also, in the first embodiment, an image of the light-emitting device 50 mounted on the substrate 40, especially an image of the light emitters 51, is captured by the second camera 140, and the position of the light-receiving device 60 is adjusted relative to the position of the captured light-emitting device 50 such that the light emitters 51 are aligned collinearly with the light-receivers 61. Captured images of the light emitters 51 and light receivers 61 are therefore used as a sort of reference marks for alignment.

Next, as illustrated by FIG. 8B, the first camera 130 is moved in the +X direction in FIG. 8B, the mounting head 120 is moved in the −Z direction in FIG. 8B to place the light-receiving device 60 on the substrate 40, and the light-receiving device 60 is bonded to the substrate 40.

As described above, in the first embodiment, the position of the light-receiving device 60 to be bonded to the substrate 40 is adjusted relative to the position of the light-emitting device 50 already bonded to the substrate 40. This method makes it possible to align the light emitters 51 collinearly with the light receivers 61 as illustrated by FIGS. 5A and 5C. When the light emitters 51 and the light receivers 61 are collinear, by properly positioning the lens sheet 30 to be bonded at a later step, the light emitters 51 and the light receivers 61 can be properly aligned with the corresponding lenses 31 such that the loss of light is reduced. This in turn increases the production yield.

In the first embodiment, the light-emitting device 50 and the light-receiving device 60 are positioned based on the positions of the light emitters 51 and the light receivers 61. Alternatively, reference marks may be provided on the light-emitting device 50 and the light-receiving device 60, and the light-emitting device 50 and the light-receiving device 60 may be positioned based on the reference marks. In this case, images of the reference marks are captured by cameras.

### Second Embodiment

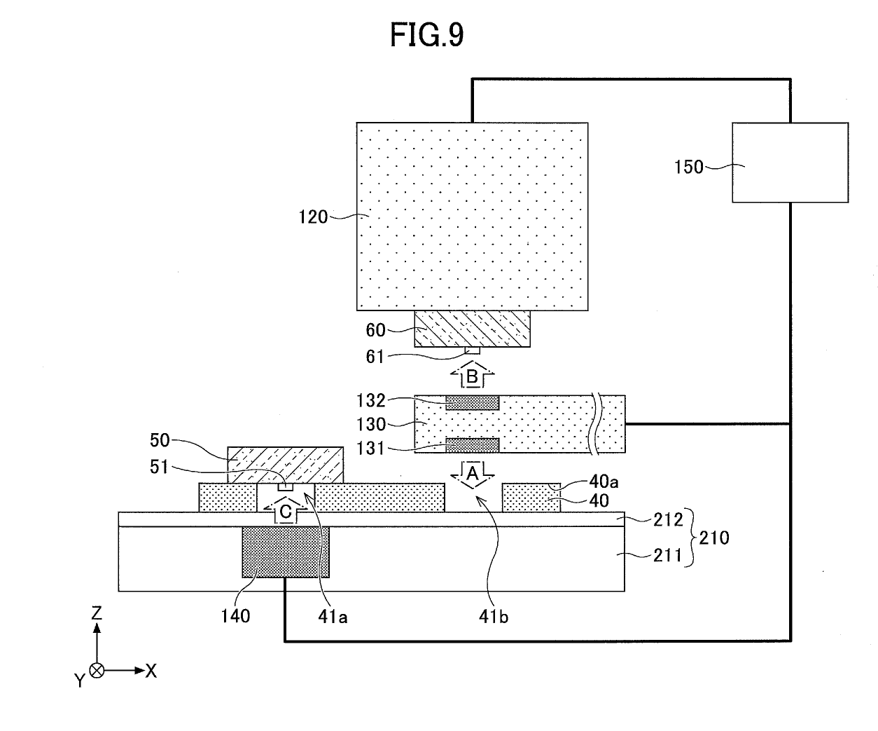

Next, a second embodiment is described. As illustrated by FIG. 9, a device mounting apparatus of the second embodiment includes a table 210 that includes a table body 211 and a transparent board 212 disposed on the table body 211. The substrate 40 is placed on an upper surface of the board 212. The second camera 140 used as the third imager is disposed on the table body 211 under the board 212. An image of the light-emitting device 50 mounted on the substrate 40 is captured by the second camera 140 via the board 212. The above configuration of the second embodiment eliminates the need to embed the second camera 140 in the table 210 and the second camera 140 can be easily installed.

The board 212 may be made of, for example, tempered glass. The second camera 140 may be movably disposed in a space formed in the table body 211. In FIG. 9, only one light emitter 51 and only one light receiver 61 are illustrated for brevity.

Other configurations of the device mounting apparatus of the second embodiment are substantially the same as those of the device mounting apparatus of the first embodiment.

### Third Embodiment

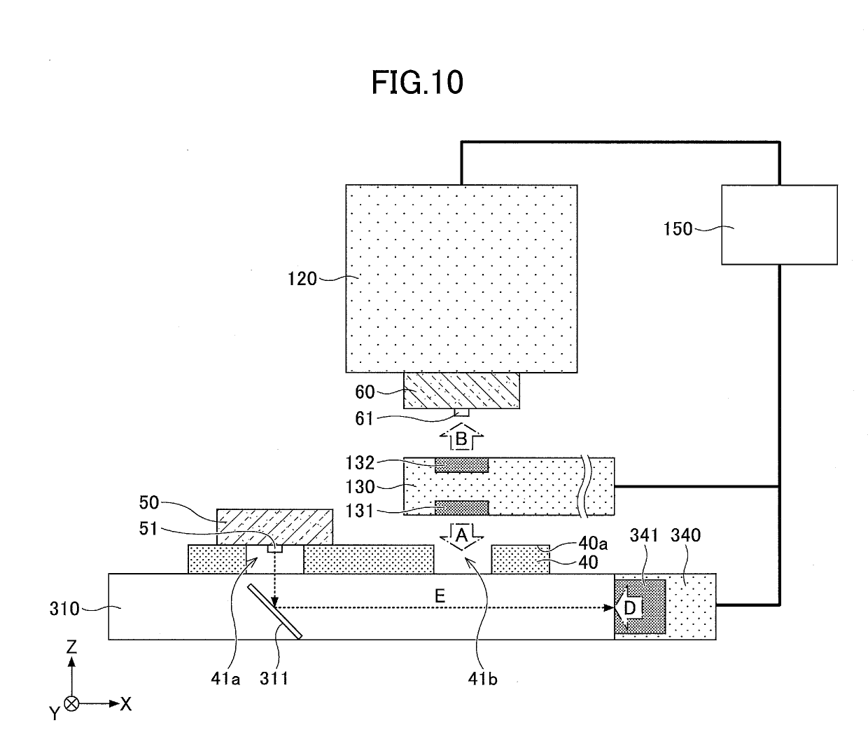

Next, a third embodiment is described. As illustrated by FIG. 10, a device mounting apparatus of the third embodiment includes a table 310 made of a transparent material. A mirror 311 is disposed in the table 310 and reflects light propagating in an in-plane direction through the table 310 at a right angle. A second camera 340 used as a third imager is disposed on a side surface of the table 310. The second camera 340 captures an image of an object located in the −X direction indicated by an arrow D, and captures an image of the light emitter 51 reflected by the mirror 311. Thus, the device mounting apparatus of the third embodiment is configured such that an image of the light emitter 51 is reflected by the mirror 311, propagates through the table 310 as indicated by an arrow E, and capture by the second camera 340. In FIG. 10, only one light emitter 51 and only one light receiver 61 are illustrated for brevity.

Other configurations of the device mounting apparatus of the third embodiment are substantially the same as those of the device mounting apparatus of the first embodiment.

### Fourth Embodiment

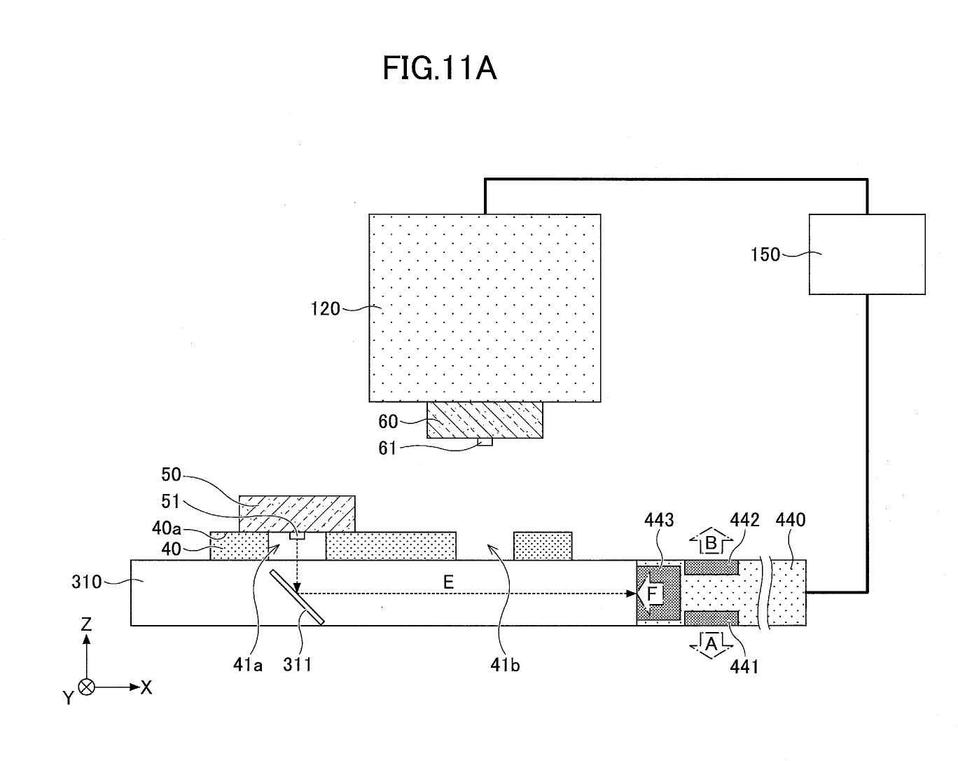

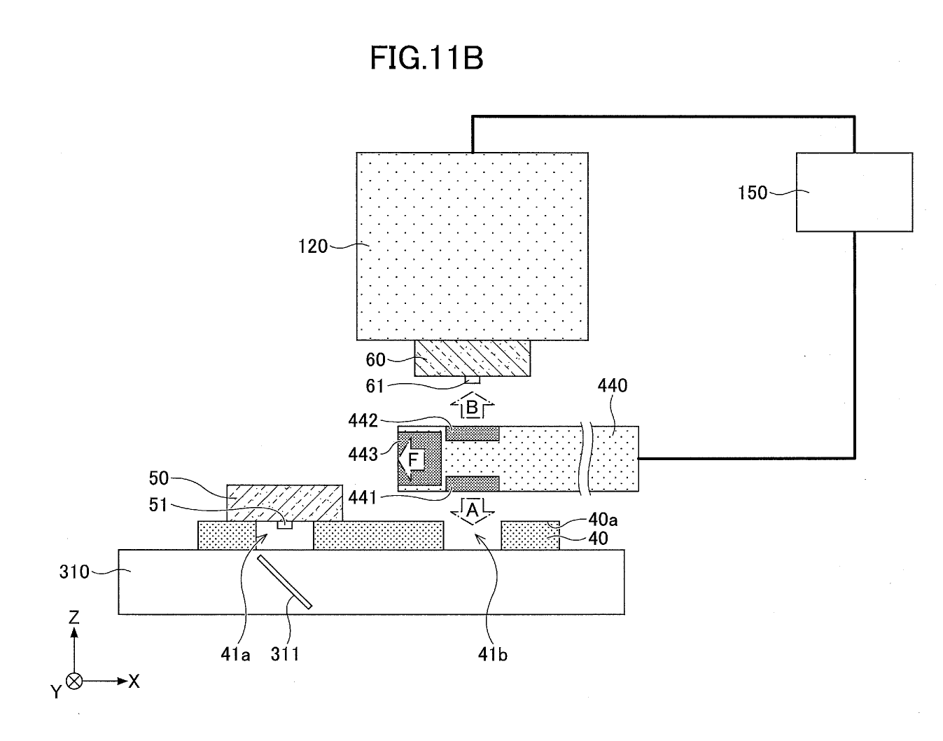

Next, a fourth embodiment is described. As illustrated by FIGS. 11A and 11B, a device mounting apparatus of the fourth embodiment includes a camera 440 that provides the functions of the first camera 130 and the second camera 340 of the third embodiment with a single unit. The camera 440 can capture images of objects in three directions. In FIGS. 11A and 11B, only one light emitter 51 and only one light receiver 61 are illustrated for brevity.

The camera 440 includes a first imager 441 on a lower surface, a second imager 442 on an upper surface, and a third imager 443 on a side surface. The first imager 441 captures an image of an object located in the −Z direction indicated by an arrow A, the second imager 442 captures an image of an object located in the +Z direction indicated by an arrow B, and the third imager 443 captures an image of an object located in the −X direction indicated by an arrow F.

The imaging direction of the first imager 441 is 180-degrees opposite the imaging direction of the second imager 442. The imaging direction of the third imager 443 forms an angle of 90 degrees with the imaging directions of the first imager 441 and the second imager 442. The third imager 443 captures, from a side surface of the transparent table 310, an image of the light-emitting device 50 reflected by the mirror 311 provided in the table 310.

In the fourth embodiment, similarly to the first embodiment, the light-emitting device 50 is bonded to the substrate 40 by using the first imager 441 and the second imager 442. Next, as illustrated by FIG. 11A, the camera 440 is moved to the side surface of the table 310, and an image of the light emitter 51 reflected by the mirror 311 is captured by the third imager 443. The captured image is sent to the controller 150 to determine the position of the light emitter 51.

Next, as illustrated by FIG. 11B, the camera 440 is moved to a position between the substrate 40 and the light-receiving device 60 held by the mounting head 120. An image of the substrate 40 is captured by the first imager 441, and an image of the light-receiving device 60 is captured by the second imager 442. Based on the position of the through hole 41b captured by the first imager 441 and the position of the light receiver 61 of the light-receiving device 60 captured by the second imager 442, the mounting head 120 is moved to align the light-receiving device 60 with the through hole 41b. In this step, the position of the light-receiving device 60 is adjusted relative to the position of the light-emitting device 50 captured by the third imager 443 such that the light emitters 51 are aligned collinearly with the light-receivers 61.

### Fifth Embodiment

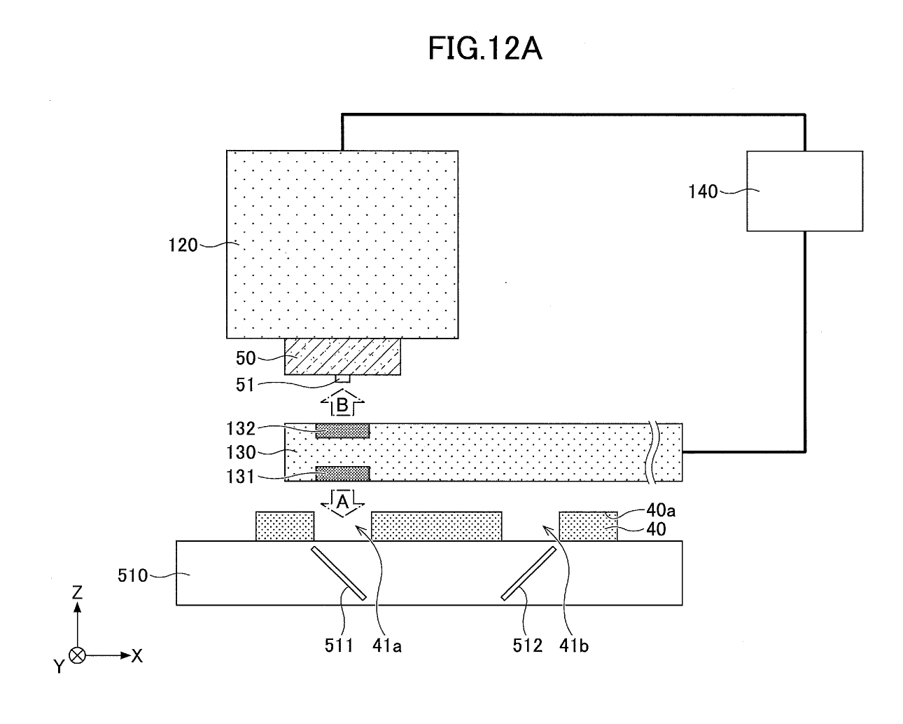

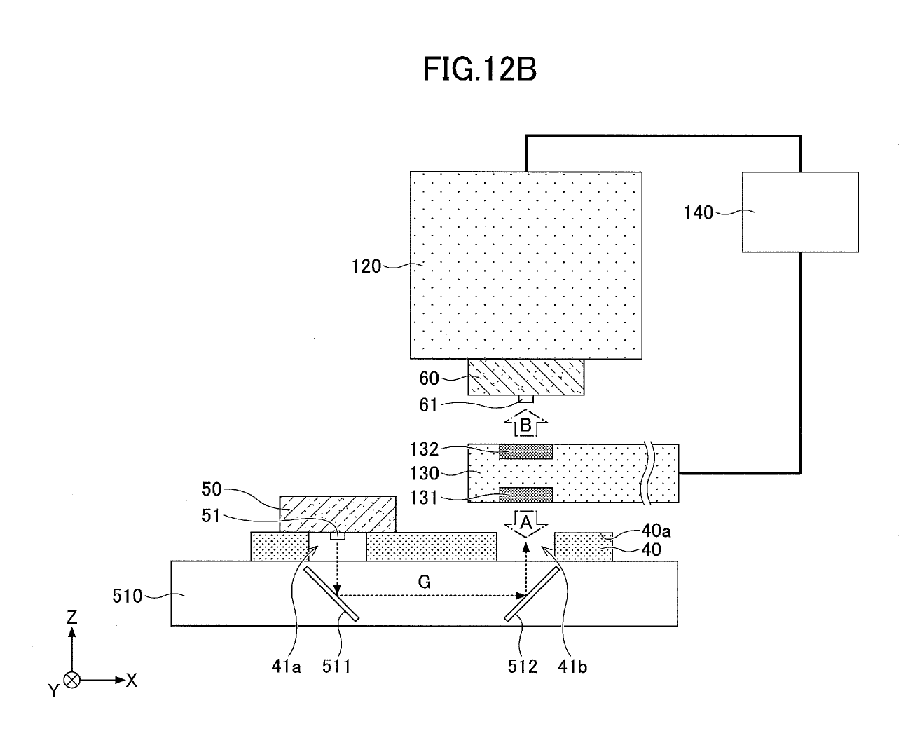

Next, a fifth embodiment is described. As illustrated by FIG. 12, a device mounting apparatus of the fifth embodiment includes a table 510 made of a transparent material. A first mirror 511 and a second mirror 512 are disposed in the table 510 and reflect light propagating in an in-plane direction through the table 510 at a right angle. The device mounting apparatus of the fifth embodiment does not include a second camera.

A device mounting method of the fifth embodiment is described with reference to FIGS. 12A and 12B. In FIGS. 12A and 12B, only one light emitter 51 and only one light receiver 61 are illustrated for brevity.

First, as illustrated by FIG. 12A, the light-emitting device 50 held by the mounting head 120 is aligned with the through hole 41a. The first camera 130 is moved to a position between the substrate 40 and the light-emitting device 50. An image of the substrate 40 is captured by the first imager 131, and an image of the light-emitting device 50 is captured by the second imager 132. Based on the image of the through hole 41a captured by the first imager 131 and the image of the light emitter 51 captured by the second imager 132, the mounting head 120 is moved such that the light emitter 51 is placed in a desired position in the through hole 41a. Then, the light-emitting device 50 is placed on and bonded to the substrate 40.

Next, as illustrated by FIG. 12B, the light-receiving device 60 held by the mounting head 120 is aligned with the through hole 41b. The first camera 130 is moved to a position between the substrate 40 and the light-receiving device 60. An image of the substrate 40 is captured by the first imager 131, and an image of the light-receiving device 60 is captured by the second imager 132. Based on the image of the through hole 41b captured by the first imager 131 and the image of the light receiver 61 captured by the second imager 132, the mounting head 120 is moved such that the light receiver 61 is placed in the through hole 41b.

At this stage, as illustrated by FIG. 12B, an image of the light emitter 51 reflected by the first and second mirrors 511 and 512 is captured by the first imager 131. As indicated by an arrow G, the image of the light emitter 51 enters the surface of the table 510 at a substantially-right angle, is reflected by the first mirror 511, propagates through the table 510, is reflected by the second mirror 512, exits from the surface of the table 510 at a substantially-right angle, passes through the through hole 41b, and enters the first imager 131.

This configuration enables the first camera 130 to detect the position of the light emitter 51, the through hole 41b, and the light receiver 61 of the light-receiving device 60 held by the mounting head 120. Based on the detected positions, the position of the light-receiving device 60 is adjusted relative to the position of the light-emitting device 50 mounted on the substrate 40 such that the light emitters 51 are aligned collinearly with the light-receivers 61. Then, the light-receiving device 60 is placed on and bonded to the substrate 40.

### Sixth Embodiment

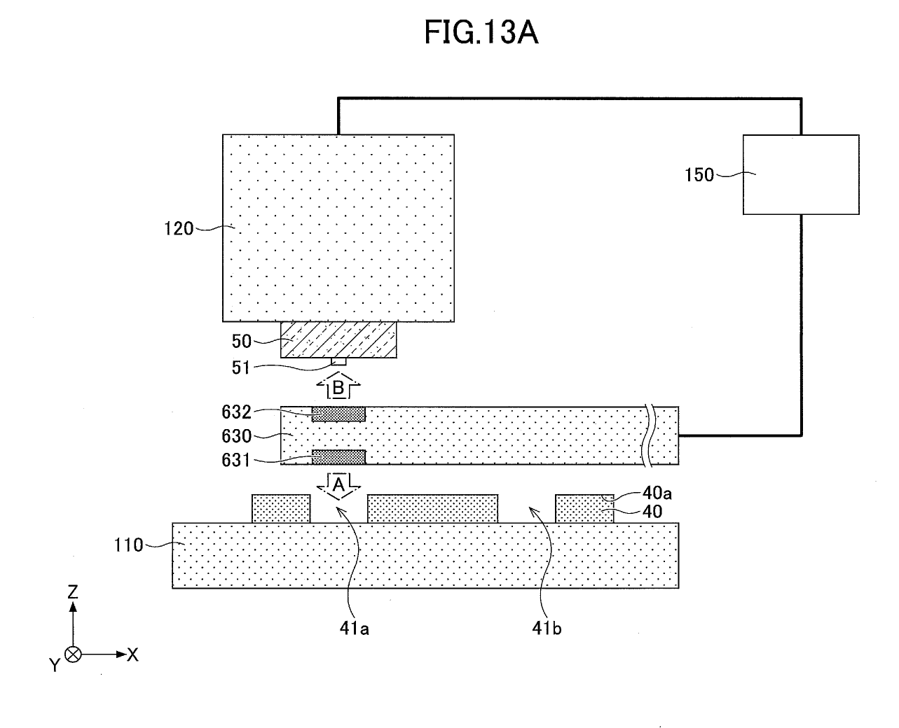

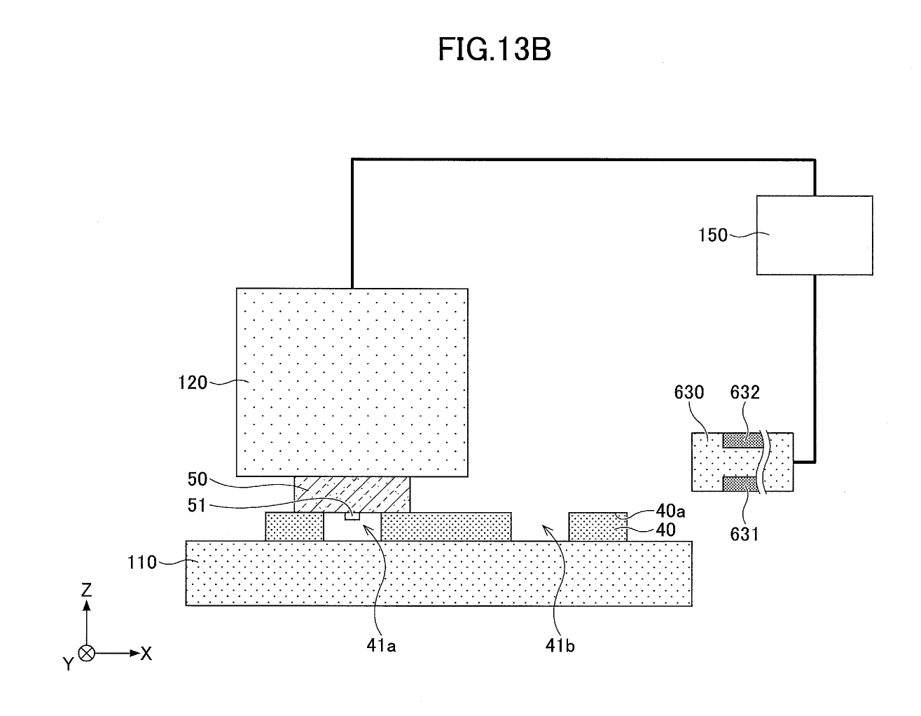

Next, a sixth embodiment is described. In the sixth embodiment, a device mounting method performed by a device mounting apparatus to produce an optical module is described. In the sixth embodiment, as illustrated in FIGS. 13A through 15, the device mounting apparatus includes a double-sided camera 630 includes a first imager 631 on a first side and a second imager 632 on a second side that can capture images of objects above and below the camera 630.

The imaging direction of the first imager 631 (indicated by the arrow A) is 180-degrees opposite the imaging direction (indicated by the arrow B) of the second imager 632 (indicated by the arrow B).

The device mounting method of the sixth embodiment is described with reference to FIGS. 13A through 16.

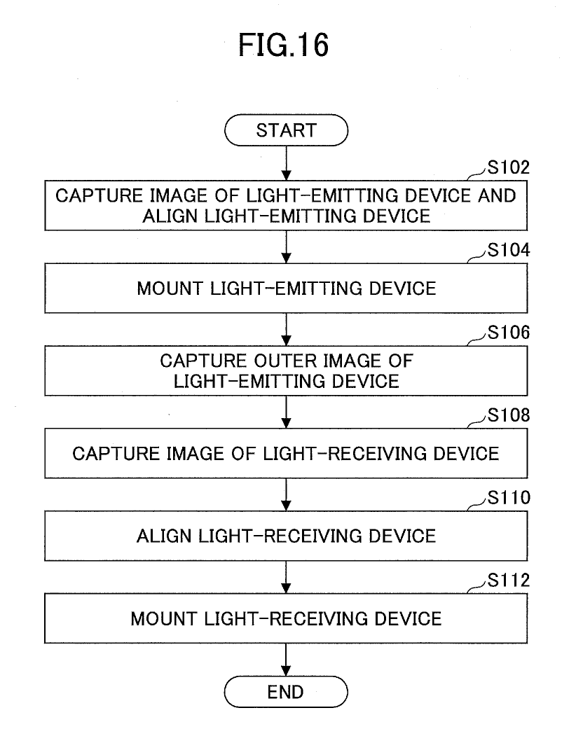

At step S102 of FIG. 16, the controller 150 causes the camera 630 to capture an image of the light-emitting device 50 held by the mounting head 120, and moves the mounting head 120 to align the light-emitting device 50 with the through hole 41a. The controller 150 moves the camera 630 to a position between the substrate 40 and the light-emitting device 50, causes the first imager 631 to capture an image of the first surface 40a, and causes the second imager 632 to capture an image of the light-emitting device 50. Based on the position of the through hole 41a captured by the first imager 631 and the position of the light emitter 51 captured by the second imager 632, the controller 150 moves the mounting head 120 to align the light-emitting device 50 with the through hole 41a such that the light emitter 51 is placed in a desired position. At this step, the controller 150 determines the outer shape of the light-emitting device 50, the position of a reference mark on the light-emitting device 50, and the position of the light emitter 51 based on the image of the light-emitting device 50 captured by the second imager 632.

At step S104, the controller 150 moves the mounting head 120 to mount the light-emitting device 50 on the substrate 40. Specifically, as illustrated by FIG. 13B, the controller 150 moves the camera 630 to the right in FIG. 13B, moves the mounting head 120 downward in FIG. 13B to place the light-emitting device 50 on the substrate 40, and bonds the light-emitting device 50 to the substrate 40 by flip-chip bonding.

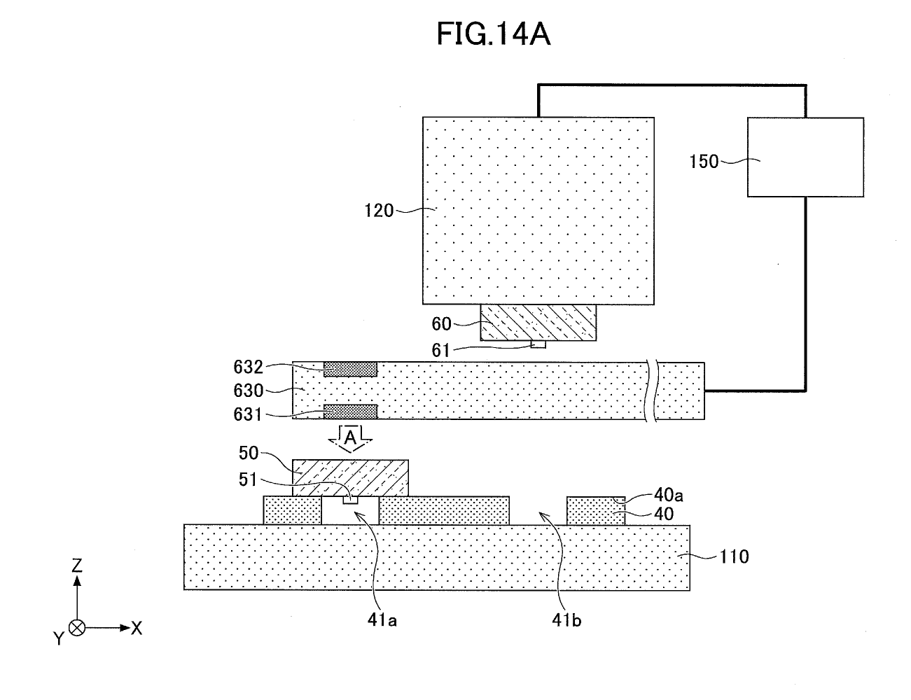

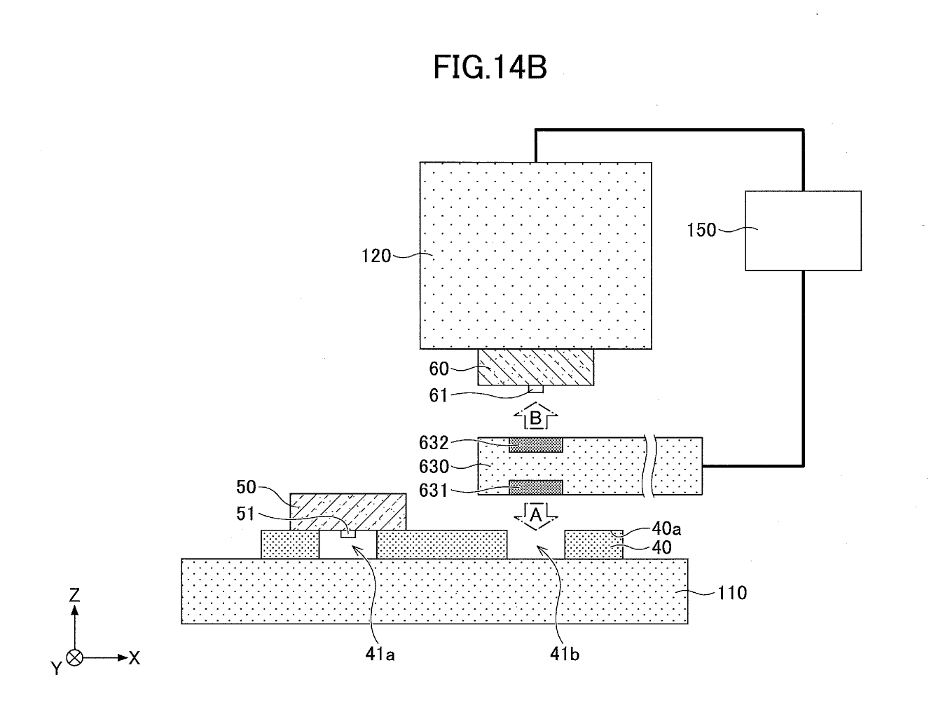

At step S106, the controller 150 causes the camera 630 to capture an outer image of the light-emitting device 50 mounted on the substrate 40. As illustrated by FIG. 14A, the controller 150 moves the camera 630 to a position above the light-emitting device 50, and causes the first imager 631 to capture an image of the light-emitting device 50. Based on the captured outer shape of the light-emitting device 50, the controller 150 estimates the position of the light emitter 51 or a reference mark on the light-emitting device 50 and stores the coordinates of the estimated position in a storage provided in the controller 150.

At step S108, the controller 150 causes the camera 630 to capture an image of the light-receiving device 60 held by the mounting head 120. The controller 150 moves the camera 630 to a position between the substrate 40 and the light-receiving device 60, causes the first imager 631 to capture an image of the first surface 40a, and causes the second imager 632 to capture an image of the light-receiving device 60. At this step, the controller 150 determines the outer shape of the light-receiving device 60, the position of a reference mark on the light-receiving device 60, and the position of the light receiver 61 based on the image of the light-receiving device 60 captured by the second imager 632.

At step S110, the controller 150 moves the mounting head 120 to position the light-receiving device 60. Specifically, the controller 150 moves the mounting head 120 to align the light-receiving device 60 with the through hole 41b based on the images of the first surface 40a and the light-receiving device 60 captured at step S108, and adjusts the position of the light receiver 61 relative to the position of the light emitter 51 or the reference mark of the light-emitting device 50 estimated at step S106.

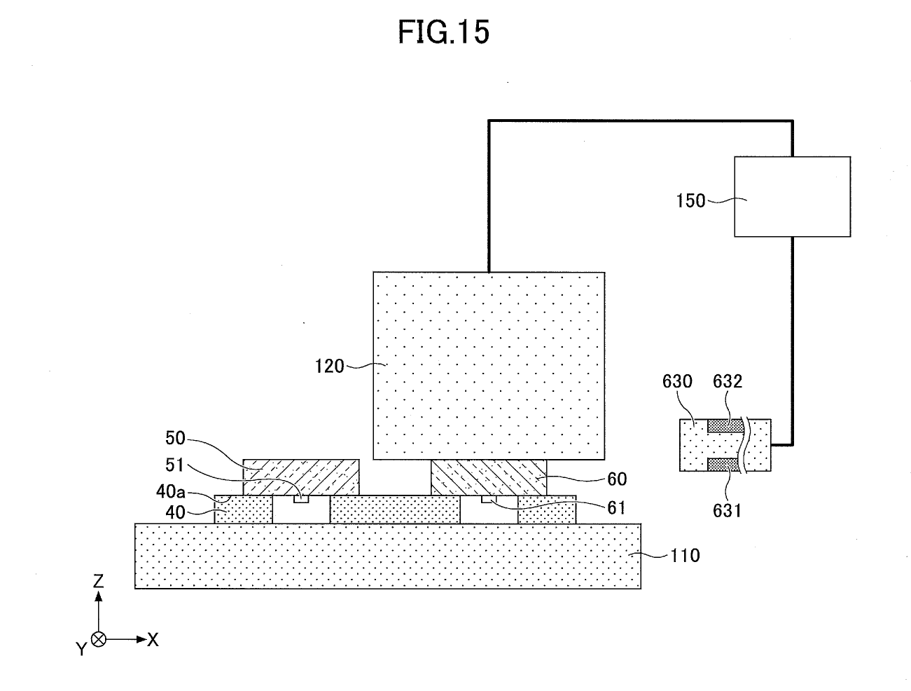

At step S112, the controller 150 moves the mounting head 120 to mount the light-receiving device 60 on the substrate 40. As illustrated by FIG. 15, the controller 150 moves the camera 630 in the +X direction, moves the mounting head 120 in the −Z direction to place the light-receiving device 60 on the substrate 40, and bonds the light-receiving device 60 to the substrate 40 by flip-chip bonding.

According to the device mounting method described above, the light-emitting device 50 and the light-receiving device 60 can be mounted on the substrate 40 such that the light emitters 51 are aligned collinearly with the light receivers 61.

An aspect of this disclosure provides a device mounting apparatus and a device mounting method that can mount a light-emitting device and a light-receiving device at accurate positions on an optical waveguide.

A device mounting apparatus and a device mounting method according to embodiments of the present invention are described above. However, the present invention is not limited to the specifically disclosed embodiments, and variations and modifications may be made without departing from the scope of the present invention.

What is claimed is:

1. A mounting apparatus for mounting a device onto a substrate, the mounting apparatus comprising:
a table that holds the substrate;
a mounting head that carries a device to be mounted on the substrate;
a camera that is movable to a position between the table and the mounting head, the camera including a first imager that captures an image of the substrate on the table and a second imager that captures images of the device carried by the mounting head;
a third imager that captures an image of a first device mounted on the substrate; and
a controller that controls the mounting head to position a second device to be mounted on the substrate and being carried by the mounting head based on a position of the first device that is determined based on the image captured by the third imager.

2. The mounting apparatus as claimed in claim 1, wherein the third imager is disposed in the table.

3. The mounting apparatus as claimed in claim 1, wherein
the table includes a table body and a transparent board disposed on the table body; and
the third imager is disposed on the table body under the transparent board.

4. The mounting apparatus as claimed in claim 1, wherein
the table is made of a transparent material and includes a mirror; and
the third imager is configured to capture the image of the first device that is reflected by the mirror.

5. A device mounting apparatus, comprising:
a transparent table that holds a substrate, the table including a mirror;
a mounting head that carries a device to be mounted on the substrate;
a camera that is movable to a position between the table and the mounting head, and includes a first imager and a second imager; and
a controller that controls the mounting head, wherein
the first imager is configured to capture an image of a first device mounted on the substrate via the mirror, and is configured to capture an image of the substrate on the table when the camera is moved to a position between the table and the mounting head;
the second imager is configured to capture an image of a second device being carried by the mounting head when the camera is moved to a position between the table and the mounting head; and
the controller is configured to mount the second device to the substrate at a position determined based on positions of the first device and the substrate that are determined based on the images captured by the first imager, and a position of the second device that is determined based on the image captured by the second imager.

6. A method for mounting devices onto a substrate performed by a device mounting apparatus that includes a table, a mounting head that carries a device to be mounted onto the substrate, and a camera having a first imager capable of capturing an image of an object at a first direction relative to the camera and a second imager capable of capturing an image of an object at a second direction relative to the camera and opposite to the first direction, the method comprising:
capturing an image of a first device mounted on the substrate;
determining a position of the first device based on the image of the first device captured;
moving the camera to a position between the substrate and the second device being carried by the mounting head;
capturing an image of the substrate by the first imager and capturing an image of the second device being carried by the mounting head by the second imager; and
mounting the second device on the substrate at a position determined based on the captured first device.

7. The method as claimed in claim 6, wherein the device mounting apparatus further includes a third imager disposed in the table; and
the image of the first device mounted on the substrate is captured by the third imager.
